(19) United States
(12) Patent Application Publication
(10) Pub. No.: US 2025/0261337 A1
(43) Pub. Date: Aug. 14, 2025

(54) PLANAR ASSEMBLY HANDLE FOR HEAT SINK OPTIMIZATION

(71) Applicant: Dell Products L.P., Round Rock, TX (US)

(72) Inventors: Eduardo ESCAMILLA, Round Rock, TX (US); Edward Gabriel Bernard CROFTS, Marlborough, MA (US)

(73) Assignee: Dell Products L.P., Round Rock, TX (US)

(21) Appl. No.: 18/441,042

(22) Filed: Feb. 14, 2024

(51) Int. Cl. H05K 7/20; F28F 9/00

(52) U.S. Cl. CPC H05K 7/2039; F28F 9/005

(57) ABSTRACT

A handle may include a first member, a second member, and a third member. The second member may extend substantially perpendicular from a first surface of the first member and may be mechanically interfaced between the first member and the third member. The third member may include a plurality of planar assembly alignment features configured to align the handle relative to a planar assembly to enable a heat sink coupled to the planar assembly to extend over the third member.

### TECHNICAL FIELD

The present disclosure relates in general to information handling systems, and more particularly to a planar assembly handle for heat sink optimization.

### BACKGROUND

As the value and use of information continues to increase, individuals and businesses seek additional ways to process and store information. One option available to users is information handling systems. An information handling system generally processes, compiles, stores, and/or communicates information or data for business, personal, or other purposes thereby allowing users to take advantage of the value of the information. Because technology and information handling needs and requirements vary between different users or applications, information handling systems may also vary regarding what information is handled, how the information is handled, how much information is processed, stored, or communicated, and how quickly and efficiently the information may be processed, stored, or communicated. The variations in information handling systems allow for information handling systems to be general or configured for a specific user or specific use such as financial transaction processing, airline reservations, enterprise data storage, or global communications. In addition, information handling systems may include a variety of hardware and software components that may be configured to process, store, and communicate information and may include one or more computer systems, data storage systems, and networking systems.

Oftentimes, information handling systems and other information handling resources (e.g., storage devices, input/output devices, and other peripheral devices) are each manufactured in a modular form factor and may be configured to be disposed in a chassis configured to receive such modular components. Such a chassis and its component modular information handling systems and information handling resources typically include various rails, carriers, and other mechanical components allowing for a person to add and remove the modular information handling systems and information handling resources from the chassis.

Such modular information handling systems frequently utilize planar assemblies to facilitate easy assembly. Handles connected to such planar assemblies may be required to lift and slide the assemblies into place in the chassis. Currently, the position of these handles may be defined by the Data Center Modular Hardware System (DC-MHS) specification, which may limit the size of nearby heat sinks. In other words, the position of a handle may often be a limiting factor for heat sink size. Accordingly, planar assembly handles configured to optimize the size of nearby heat sinks may be desirable.

### SUMMARY

In accordance with the teachings of the present disclosure, the disadvantages and problems associated with existing approaches to positioning handles on planar assemblies may be reduced or eliminated.

In accordance with embodiments of the present disclosure, a handle may include a first member, a second member, and a third member. The second member may extend substantially perpendicular from a first surface of the first member and may be mechanically interfaced between the first member and the third member. The third member may include a plurality of planar assembly alignment features configured to align the handle relative to a planar assembly to enable a heat sink coupled to the planar assembly to extend over the third member.

In accordance with embodiments of the present disclosure, a system may include a planar assembly configured to couple to a heat sink and a handle mechanically coupled to the planar assembly. The handle May include a first member, a second member, and a third member. The second member may extend substantially perpendicular from a first surface of the first member and may be mechanically interfaced between the first member and the third member. The third member may include a plurality of planar assembly alignment features configured to align the handle relative to a planar assembly to enable a heat sink coupled to the planar assembly to extend over the third member.

In accordance with embodiments of the present disclosure, a method may include aligning a handle with a planar assembly, wherein the planar assembly may be configured to couple to a heat sink, and coupling the handle to the planar assembly. The handle may include a first member, a second member, and a third member. The second member may extend substantially perpendicular from a first surface of the first member and may be mechanically interfaced between the first member and the third member. The third member may include a plurality of planar assembly alignment features configured to align the handle relative to a planar assembly to enable a heat sink coupled to the planar assembly to extend over the third member.

It is to be understood that both the foregoing general description and the following detailed description are examples and explanatory and are not restrictive of the claims set forth in this disclosure.

### BRIEF DESCRIPTION OF THE DRAWINGS

A more complete understanding of the present embodiments and advantages thereof may be acquired by referring to the following description taken in conjunction with the accompanying drawings, in which like reference numbers indicate like features, and wherein:

FIG. 1A illustrates a perspective view of an example planar assembly coupled to an example T-handle, as is known in the art;

FIG. 1B illustrates a perspective view of an example planar assembly coupled to an example T-handle and an example heat sink, as is known in the art;

FIG. 2 illustrates a perspective view of an example handle, in accordance with embodiments of the present disclosure; and

FIG. 3 illustrates a perspective view of an example planar assembly coupled to an example handle and example heat sink, in accordance with embodiments of the present disclosure.

### DETAILED DESCRIPTION

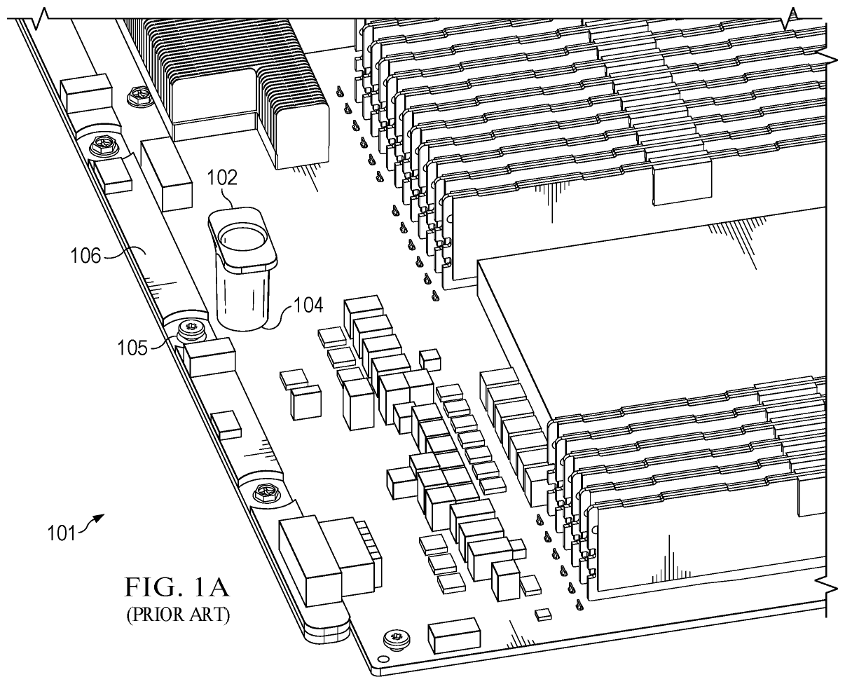

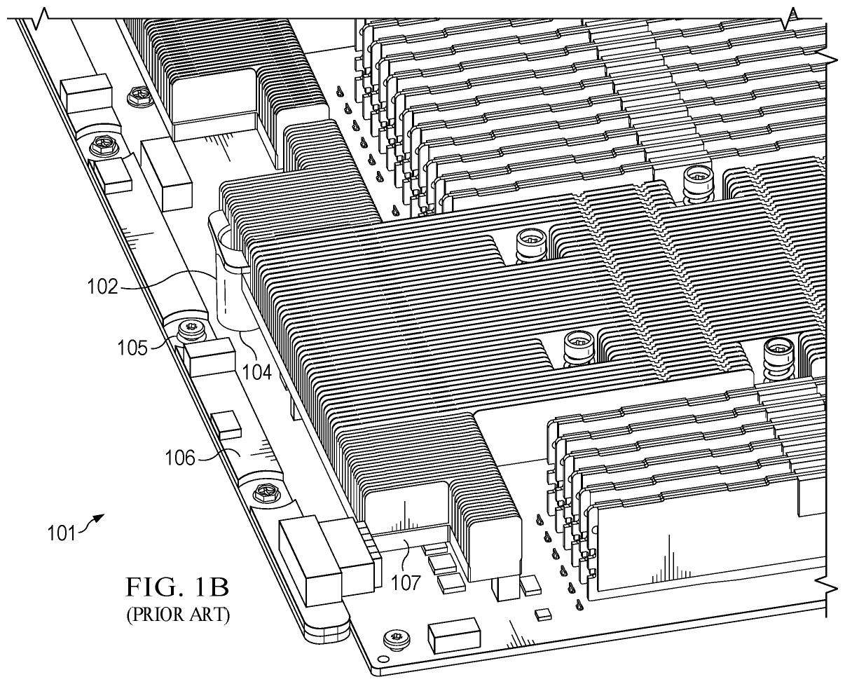

Preferred embodiments and their advantages are best understood by reference to FIGS. 1A through 3, wherein like numbers are used to indicate like and corresponding parts.

For the purposes of this disclosure, an information handling system may include any instrumentality or aggregate of instrumentalities operable to compute, classify, process, transmit, receive, retrieve, originate, switch, store, display, manifest, detect, record, reproduce, handle, or utilize any form of information, intelligence, or data for business, scientific, control, entertainment, or other purposes. For example, an information handling system may be a personal computer, a personal data assistant (PDA), a consumer electronic device, a network storage device, or any other suitable device and may vary in size, shape, performance, functionality, and price. The information handling system may include memory, one or more processing resources such as a central processing unit (CPU) or hardware or software control logic. Additional components of the information handling system may include one or more storage devices, one or more communications ports for communicating with external devices as well as various input and output (I/O) devices, such as a keyboard, a mouse, and a video display. The information handling system may also include one or more buses operable to transmit communication between the various hardware components.

For the purposes of this disclosure, computer-readable media may include any instrumentality or aggregation of instrumentalities that may retain data and/or instructions for a period of time. Computer-readable media may include, without limitation, storage media such as a direct access storage device (e.g., a hard disk resource or floppy disk), a sequential access storage device (e.g., a tape disk resource), compact disk, CD-ROM, DVD, random access memory (RAM), read-only memory (ROM), electrically erasable programmable read-only memory (EEPROM), and/or flash memory; as well as communications media such as wires, optical fibers, microwaves, radio waves, and other electromagnetic and/or optical carriers; and/or any combination of the foregoing.

For the purposes of this disclosure, information handling resources may broadly refer to any component system, device or apparatus of an information handling system, including without limitation processors, buses, memories, I/O devices and/or interfaces, storage resources, network interfaces, motherboards, integrated circuit packages; electro-mechanical devices (e.g., air movers), displays, and power supplies.

For the purposes of this disclosure, a circuit board may broadly refer to a printed circuit board (PCB), printed wiring board (PWB), printed wiring assembly (PWA) etched wiring board, and/or any other board or similar physical structure operable to mechanically support and electrically couple electronic components (e.g., packaged integrated circuits, slot connectors, etc.). A circuit board may comprise a substrate of a plurality of conductive layers separated and supported by layers of insulating material laminated together, with conductive traces disposed on and/or in any of such conductive layers, with vias for coupling conductive traces of different layers together, and with pads for coupling electronic components (e.g., packaged integrated circuits, slot connectors, etc.) to conductive traces of the circuit board.

FIGS. 1A and 1B illustrate perspective views of an example planar assembly 101 coupled to an example T-handle 102, as is known in the art. While not shown, planar assembly 101 may couple to a tempan, which may couple to a chassis. As shown in FIGS. 1A and 1B, planar assembly 101 may comprise a plurality of information handling resources coupled thereto. Planar assembly 101 may further comprise attach point hole 104 and attach point hole 105. Attach point hole 105 may be located closer to an edge of planar assembly 101 than attach point hole 104. In some embodiments, attach point hole 105 may comprise a fan board mounting hole, which may be used to couple fan board 106 to planar assembly 101.

As shown in FIGS. 1A and 1B, T-handle 102 may couple to planar assembly 101 at attach point hole 104 such that a lift point (e.g., a point at which a user grips T-handle 102 to couple and uncouple planar assembly 101 from a chassis) of planar assembly 101 may be located at attach point hole 104. As shown in FIG. 1B, coupling of T-handle 102 to planar assembly 101 at attach point hole 104 may limit a size of heat sink 107 coupled to planar assembly 101.

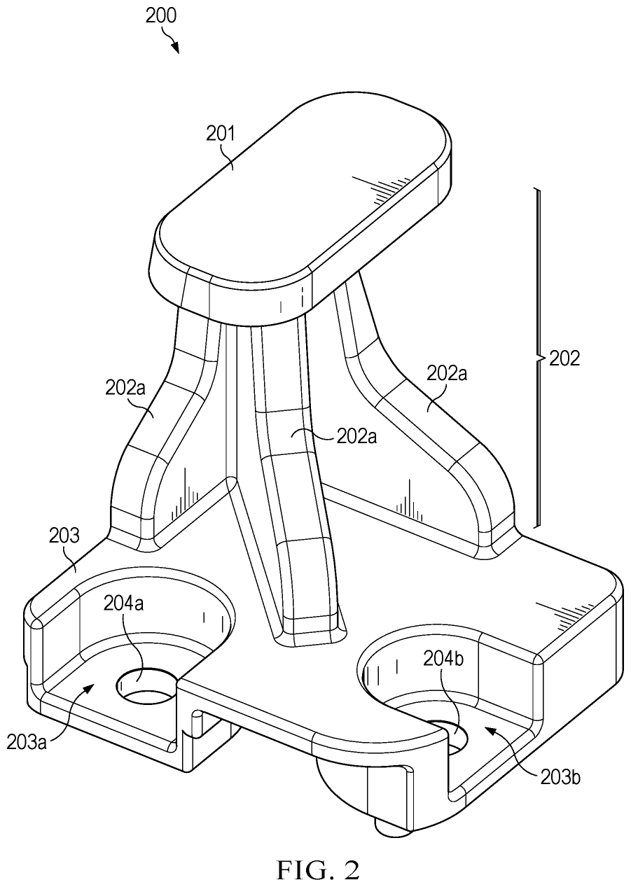

FIG. 2 illustrates a perspective view of an example handle 200, in accordance with embodiments of the present disclosure. Handle 200 may be configured to mechanically couple to planar assembly 101 of FIG. 1 to enable a user to remove planar assembly 101 from a chassis. As shown in FIG. 2, handle 200 may comprise a top 201, an intermediary structure 202, and a base 203. Top 201 may be offset relative to base 203 (e.g., a center of top 201 may be offset from a center of base 203). While FIG. 2 shows top 201 comprising an oval or oblong shape, top 201 may comprise any suitable shape.

Intermediary structure 202 may extend substantially perpendicular “down” from a bottom surface of top 201 and couple substantially perpendicular to a top surface of base 203. In some embodiments, intermediary structure 202 may comprise a plurality of members 202a. While FIG. 2 shows intermediary structure 202 comprising three members 202a, intermediary structure 202 may comprise any suitable number of members 202a.

Base 203 may comprise recess 203a and recess 203b. Recess 203a may comprise hole 204a and be configured to align with an attach point hole a planar assembly, as described in greater detail below. Recess 203b may comprise a hole 204b and be configured to align with another attach point hole of the planar assembly, as described in greater detail below. As described further below, handle 200 may be configured such that when handle 200 is coupled to the planar assembly, a heat sink coupled to the planar assembly may extend over recess 203b. While FIG. 2 shows base 203 comprising a substantially rectangular shape, base 203 may comprise any suitable shape.

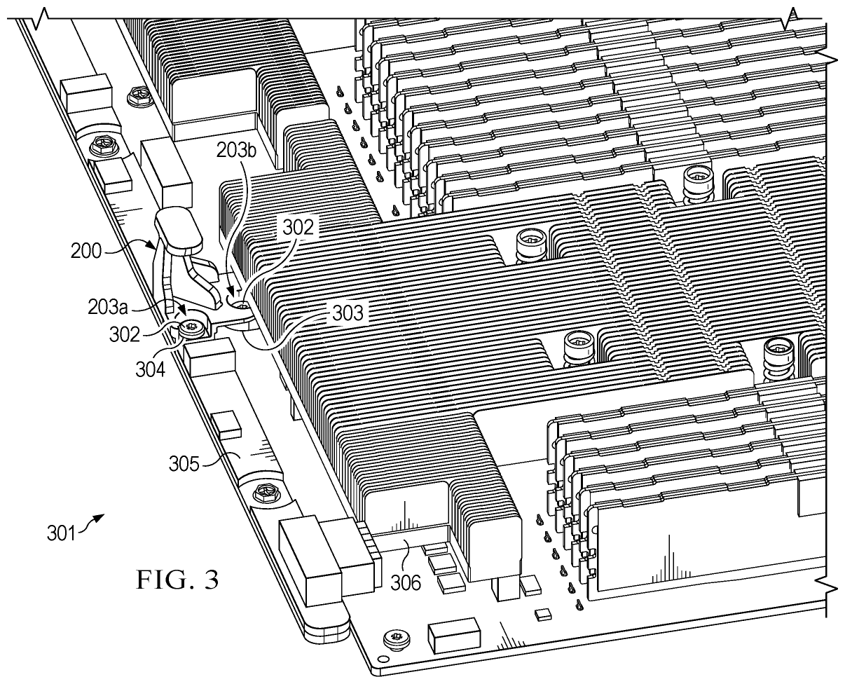

FIG. 3 illustrates a perspective view of example planar assembly 301 coupled to an example handle 200 and example heat sink 306, in accordance with embodiments of the present disclosure. As shown in FIG. 3, recess 203a of base 203 may align with attach point hole 304, and recess 203b of base 203 may align with attach point hole 303. Fasteners 302 may extend through hole 204a of recess 203a and attach point hole 304, and through hole 204b of recess 203b and attach point hole 303, to mechanically couple handle 200 to planar assembly 301. As shown in FIG. 3, handle 200 may be configured such that when handle 200 is coupled to planar assembly 301, heat sink 306 may extend over recess 203b. In some embodiments, attach point hole 304 may further be configured to enable coupling of an information handling resource 305 to planar assembly 301.

In operation, a user may grip handle 200 via top 201 to lift and slide planar assembly 301 into and out of a chassis. As described above, handle 200 may be configured such that heat sink 306 may extend over recess 203b. Thus, relative to a heat sink coupled to planar assembly 301 coupled to T-handle 102, heat sink 306 may be longer in length. In some embodiments, handle 200 may enable heat sink 306 to be up to approximately 20 mm longer than a heat sink coupled to planar assembly 301 coupled to T-handle 102 instead of handle 200.

As used herein, when two or more elements are referred to as “coupled” to one another, such term indicates that such two or more elements are in electronic communication or mechanical communication, as applicable, whether connected indirectly or directly, with or without intervening elements.

This disclosure encompasses all changes, substitutions, variations, alterations, and modifications to the example embodiments herein that a person having ordinary skill in the art would comprehend. Similarly, where appropriate, the appended claims encompass all changes, substitutions, variations, alterations, and modifications to the example embodiments herein that a person having ordinary skill in the art would comprehend. Moreover, reference in the appended claims to an apparatus or system or a component of an apparatus or system being adapted to, arranged to, capable of, configured to, enabled to, operable to, or operative to perform a particular function encompasses that apparatus, system, or component, whether or not it or that particular function is activated, turned on, or unlocked, as long as that apparatus, system, or component is so adapted, arranged, capable, configured, enabled, operable, or operative. Accordingly, modifications, additions, or omissions may be made to the systems, apparatuses, and methods described herein without departing from the scope of the disclosure. For example, the components of the systems and apparatuses may be integrated or separated. Moreover, the operations of the systems and apparatuses disclosed herein may be performed by more, fewer, or other components and the methods described may include more, fewer, or other steps. Additionally, steps may be performed in any suitable order. As used in this document, “each” refers to each member of a set or each member of a subset of a set.

Although exemplary embodiments are illustrated in the figures and described below, the principles of the present disclosure may be implemented using any number of techniques, whether currently known or not. The present disclosure should in no way be limited to the exemplary implementations and techniques illustrated in the drawings and described above.

Unless otherwise specifically noted, articles depicted in the drawings are not necessarily drawn to scale.

All examples and conditional language recited herein are intended for pedagogical objects to aid the reader in understanding the disclosure and the concepts contributed by the inventor to furthering the art, and are construed as being without limitation to such specifically recited examples and conditions. Although embodiments of the present disclosure have been described in detail, it should be understood that various changes, substitutions, and alterations could be made hereto without departing from the spirit and scope of the disclosure.

Although specific advantages have been enumerated above, various embodiments may include some, none, or all of the enumerated advantages. Additionally, other technical advantages may become readily apparent to one of ordinary skill in the art after review of the foregoing figures and description.

To aid the Patent Office and any readers of any patent issued on this application in interpreting the claims appended hereto, applicants wish to note that they do not intend any of the appended claims or claim elements to invoke 35 U.S.C. § 112 (f) unless the words “means for” or “step for” are explicitly used in the particular claim.

What is claimed is:

1. A handle comprising:
a first member;
a second member, wherein the second member extends substantially perpendicular from a first surface of the first member and is mechanically interfaced between the first member and a third member; and
the third member, wherein the third member comprises a plurality of planar assembly alignment features configured to align the handle relative to a planar assembly to enable a heat sink coupled to the planar assembly to extend over the third member.

2. The handle of claim 1, wherein the handle is configured to facilitate coupling and uncoupling of the planar assembly to a chassis.

3. The handle of claim 1, wherein the plurality of planar assembly alignment features comprises a first recess comprising a first hole and a second recess comprising a second hole.

4. The handle of claim 3, wherein the first recess is configured to enable the heat sink to extend over the first recess.

5. The handle of claim 3, wherein the first hole and the second hole are each configured to receive a fastener configured to mechanically couple the handle to the planar assembly.

6. The handle of claim 3, wherein the first hole is configured to align with a first attach point hole of the planar assembly and the second hole is configured to align with a second attach point hole of the planar assembly.

7. The handle of claim 6, wherein the second attach point hole is configured to enable coupling of an information handling resource to the planar assembly.

8. A system comprising:
a planar assembly configured to couple to a heat sink; and
a handle mechanically coupled to the planar assembly, the handle comprising:
a first member;
a second member, wherein the second member extends substantially perpendicular from a first surface of the first member and is mechanically interfaced between the first member and a third member; and
the third member, wherein the third member comprises a plurality of planar assembly alignment features configured to align the handle relative to a planar assembly to enable a heat sink coupled to the planar assembly to extend over the third member.

9. The system of claim 8, wherein the handle is configured to facilitate coupling and uncoupling of the planar assembly to a chassis.

10. The system of claim 8, wherein the plurality of planar assembly alignment features comprises a first recess comprising a first hole and a second recess comprising a second hole.

11. The system of claim 10, wherein the first recess is configured to enable the heat sink to extend over the first recess.

12. The system of claim 10, wherein the first hole and the second hole are each configured to receive a fastener configured to mechanically couple the handle to the planar assembly.

13. The system of claim 10, wherein the first hole is configured to align with a first attach point hole of the planar assembly and the second hole is configured to align with a second attach point hole of the planar assembly.

14. The system of claim 13, wherein the second attach point hole is configured to enable coupling of an information handling resource to the planar assembly.

15. A method comprising:
aligning a handle with a planar assembly, wherein the planar assembly is configured to couple to a heat sink; and
coupling the handle to the planar assembly, wherein the handle comprises:
a first member;
a second member, wherein the second member extends substantially perpendicular from a first surface of the first member and is mechanically interfaced between the first member and a third member; and
the third member, wherein the third member comprises a plurality of planar assembly alignment features configured to align the handle relative to a planar assembly to enable a heat sink coupled to the planar assembly to extend over the third member.

16. The method of claim 15, wherein the handle is configured to facilitate coupling and uncoupling of the planar assembly to a chassis.

17. The method of claim 15, wherein the plurality of planar assembly alignment features comprises a first recess comprising a first hole and a second recess comprising a second hole.

18. The method of claim 17, wherein the heat sink extends over the first recess.

19. The method of claim 17, wherein the first hole and the second hole are each configured to receive a fastener configured to mechanically couple the handle to the planar assembly.

20. The method of claim 17, wherein the first hole is configured to align with a first attach point hole of the planar assembly and the second hole is configured to align with a second attach point hole of the planar assembly.

21. The method of claim 20, wherein the first attach point hole is configured to enable coupling of an information handling resource to the planar assembly.
